(19) United States
(12) Patent Application Publication
(10) Pub. No.: US 2024/0258330 A1
(43) Pub. Date: Aug. 1, 2024

(54) DISPLAY DEVICE AND TILING DISPLAY APPARATUS INCLUDING THE SAME

(71) Applicant: LG Display Co., Ltd., Seoul (KR)

(72) Inventors: Hyokyeong SON, Seoul (KR); Won-Gyu JEONG, Paju-si (KR); Eun-Soo CHANG, Paju-si (KR); Byonghoo KIM, Paju-si (KR)

(73) Assignee: LG Display Co., Ltd., Seoul (KR)

(21) Appl. No.: 18/423,576

(22) Filed: Jan. 26, 2024

(30) Foreign Application Priority Data
Jan. 31, 2023 (KR) 10-2023-0013310

(51) Int. Cl. H01L 27/12; H01L 25/16

(52) U.S. Cl. CPC H01L 27/124; H01L 25/167

(57) ABSTRACT

A display device includes a substrate including a front panel area, a back panel area, and a bendable area disposed between the front panel area and the back panel area; a display area located on the substrate and in the front panel area and having a plurality of light-emitting elements; an integrated circuit chip located on the substrate and in the back panel area; and a side wiring portion located on the substrate and in the bendable area so as to electrically connect the light-emitting elements and the integrated circuit chip to each other, wherein the side wiring portion includes a conductive connection portion, and a protecting portion covering the conductive connection portion.

### CROSS-REFERENCE TO RELATED APPLICATION

This application claims priority from Korean Patent Application No. 10-2023-0013310 filed on Jan. 31, 2023, in the Korean Intellectual Property Office, and all the benefits accruing therefrom under 35 U.S.C. 119. The contents of the above prior Korean patent application in their entirety are herein incorporated by reference.

### BACKGROUND

### Field

The present disclosure relates to a display device, and more specifically, a display device and a tiling display apparatus including the same.

### Description of Related Art

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein, and displays information using light generated from the built-in light-emitting element or light source. A display device including a self-light-emitting element may be implemented to be thinner than a display device with the built-in light source and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

### SUMMARY

A purpose according to embodiments of the present disclosure is to provide a display device in which a display area where an image is displayed and a peripheral area that transmits signals to the display area may be implemented using a single flexible substrate.

Furthermore, a purpose according to embodiments of the present disclosure is to provide a display device in which an integrated side wiring portion is disposed on a single flexible substrate so as to stably supply signals.

Furthermore, a purpose according to embodiments of the present disclosure is to provide a display device in which a substrate is made of a lightweight material to allow the display device to be lightweight.

Purposes of the present disclosure are not limited to the above-mentioned purpose. Other purposes and advantages of the present disclosure that are not mentioned may be understood based on following descriptions and may be more clearly understood based on embodiments of the present disclosure. Further, it will be easily understood that the purposes and advantages of the present disclosure may be realized using means shown in the claims and combinations thereof.

One aspect of the present disclosure provides a display device comprising: a substrate including a front panel area, a back panel area, and a bendable area disposed between the front panel area and the back panel area; a display area located on the substrate and in the front panel area and having a plurality of light-emitting elements disposed therein; an integrated circuit chip located on the substrate and in the back panel area; and a side wiring portion located on the substrate and in the bendable area so as to electrically connect the light-emitting elements and the integrated circuit chip to each other, wherein the side wiring portion includes a conductive connection portion, and a protecting portion covering the conductive connection portion.

Another aspect of the present disclosure provides a tiling display apparatus in which a plurality of display devices are arranged such that bendable areas of substrates thereof are adjacent to each other, wherein each of the plurality of display devices includes: a substrate including a front panel area, a back panel area, and a bendable area disposed between the front panel area and the back panel area; a display area located on the substrate and in the front panel area and having a plurality of light-emitting elements disposed therein; an integrated circuit chip located on the substrate and in the back panel area; and a side wiring portion located on the substrate and in the bendable area so as to electrically connect the light-emitting elements and the integrated circuit chip to each other, wherein the side wiring portion includes a conductive connection portion, and a protecting portion covering the conductive connection portion.

According to one embodiment of the present disclosure, the display device may be manufactured using one substrate, such that a process of separately manufacturing an upper substrate and a lower substrate and bonding the upper substrate and the lower substrate to each other may be omitted, thereby optimizing the process to reduce production energy consumption.

Furthermore, the side wiring portion that applies the signal to the display area where the light-emitting element is disposed extends from the front panel area across the bendable area to the back panel area, thereby preventing the side wiring from being discontinuous in the bendable area, and thus improving the reliability of the product.

Furthermore, the conductive connection portion and the protecting portion of the side wiring portion are formed in an integrated manner with each other, thereby preventing cracks from occurring in the conductive connection portion or preventing change in an electrical resistance of the conductive connection portion. Thus, the reliability of the display device may be improved.

Furthermore, the substrate is made of a flexible and lightweight material, thereby reducing the weight of the product.

Furthermore, the support member disposed in the space defined between the front panel area and the back panel area facing each other may supplement rigidity of the substrate while maintaining the flexibility of the substrate, thereby preventing circuit elements and light-emitting elements from being damaged by external impacts.

Effects of the present disclosure are not limited to the effects mentioned above, and other effects not mentioned will be clearly understood by those skilled in the art from the descriptions below.

The purposes, solutions, and effects of the disclosure as described above does not specify essential features of claims. Thus, the scope of claims is not limited by the purposes, solutions, and effects of the disclosure as described above.

It is to be understood that both the foregoing general description and the following detailed description of the present disclosure are by way of example and are intended to provide further explanation of the disclosures.

### BRIEF DESCRIPTION OF DRAWINGS

The accompanying drawings, which are included to provide a further understanding of the disclosure and are incorporated in and constitute a part of this application, illustrate example embodiments of the disclosure and together with the description serve to explain the principles of the disclosure.

FIG. 1 is a schematic plan view of a tiling display apparatus according to an embodiment of the present disclosure.

FIG. 2 is a schematic plan view showing one of a plurality of tiling display panel units such as an area 2 in FIG. 1.

FIG. 3 is a cross-sectional view of a display device taken along line 5-5 in FIG. 2 according to one embodiment of the present disclosure.

FIG. 4 is an enlarged view of an area 4 in FIG. 3.

FIG. 5 to FIG. 8 are drawings for illustrating a side wiring portion, wherein FIG. 8 is an enlarged view of an area 8 in FIG. 7.

FIG. 9 is a graph showing change in an electrical resistance during bending deformation.

FIG. 10 to FIG. 12 are cross-sectional views showing a shape of a support member.

FIG. 13 is a cross-sectional view of a display device according to another embodiment of the present disclosure.

FIG. 14 is a cross-sectional view of a display device according to still another embodiment of the present disclosure.

FIG. 15 is a cross-sectional view of a display device according to still yet another embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including,” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of,” when preceding a list of elements, may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer or may be disposed indirectly on the second element or layer with a third element or layer being disposed between the first and second elements or layers.

It will be understood that when an element or layer is referred to as being “connected to” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter, or still another layer, film, region, plate, or the like may be disposed between the former and the latter. As used herein, when a layer, film, region, plate, or the like is “directly” disposed “on” or “on a top” of another layer, film, region, plate, or the like, the former directly contacts the latter. Further, as used herein, when a layer, film, region, plate, or the like is disposed “below” or “under” another layer, film, region, plate, or the like, the former may directly contact the latter, or still another layer, film, region, plate, or the like may be disposed between the former and the latter. As used herein, when a layer, film, region, plate, or the like is “directly” disposed “below” or “under” another layer, film, region, plate, or the like, the former directly contacts the latter.

In descriptions of temporal relationships, for example, temporal precedent relationships between two events such as “after,” “subsequent to,” “before,” etc., another event may occur therebetween unless “directly after,” “directly subsequent,” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or sections, these elements, components, regions, layers and/or sections should not be limited by these terms. These terms are used to refer to one element, component, region, layer or section separately from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

As used herein, “embodiments,” “examples,” “aspects,” and the like should not be construed such that any aspect or design as described is superior to or advantageous over other aspects or designs.

Further, the term “or” means “inclusive or” rather than “exclusive or.” That is, unless otherwise stated or clear from the context, the expression that “x uses a or b” means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each of embodiments of the present disclosure will be described with reference to the attached drawings.

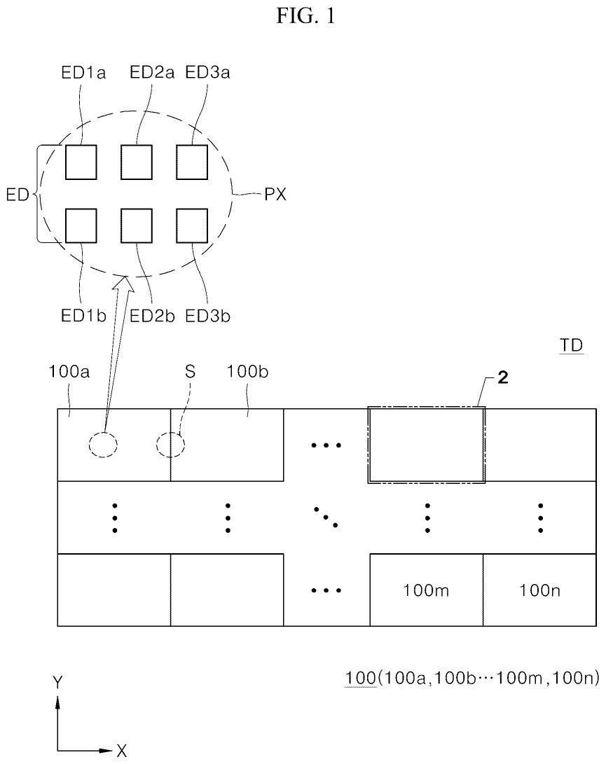

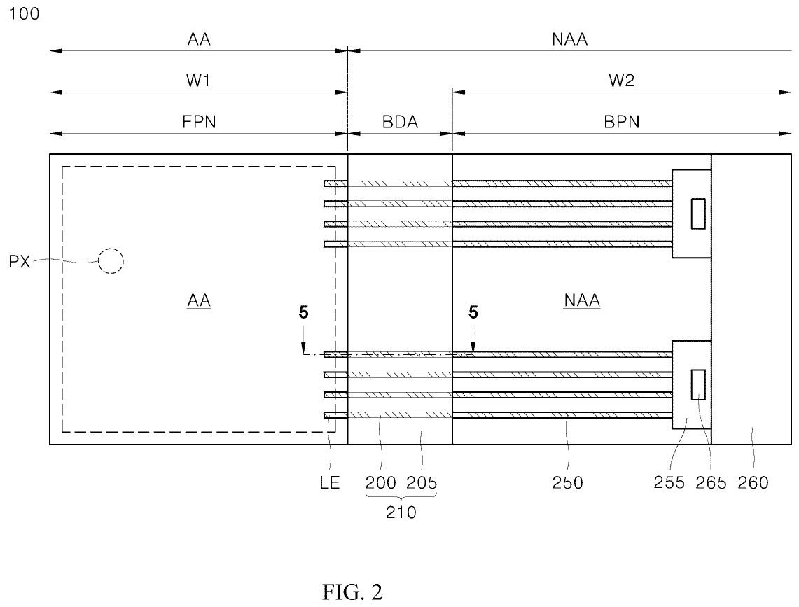

FIG. 1 is a schematic plan view of a tiling display apparatus according to an embodiment of the present disclosure. FIG. 2 is a schematic plan view showing one of a plurality of tiling display panel units in FIG. 1.

With reference to FIG. 1 and FIG. 2, a tiling display apparatus TD according to an embodiment of the present disclosure may be configured to include a plurality of display devices 100a, 100b, . . . 100m, and 100n. In this regard, m and n may be natural numbers. The display devices 100a, 100b, . . . 100m, and 100n may be arranged in a first direction X and a second direction Y that intersects the first direction X such that adjacent display devices contact each other. In this regard, the first direction X may be a row direction, while the second direction Y may be a column direction.

Each of a plurality of pixels PX arranged in each of the plurality of display devices 100a, 100b, . . . 100m, and 100n may include a plurality of sub-pixels. Each sub-pixel may include a light-emitting unit and a circuit unit for driving the light-emitting unit. The light-emitting unit may include a light-emitting element ED. The light-emitting element ED may include at least one light-emitting element ED arranged in each of the plurality of sub-pixels. For example, the light-emitting element ED may include a first light-emitting element ED1a, a second light-emitting element ED2a or a third light-emitting element ED3a that emits red (R), green (G), or blue (B) light, respectively. However, the present disclosure is not limited thereto. For example, each sub-pixel may further include a white light-emitting element that emits white light.

Furthermore, each of the plurality of sub-pixels may further include each of a plurality of redundant light-emitting elements for a repair process. For example, the redundant light-emitting element may include a first redundant light-emitting element ED1b, a second redundant light-emitting element ED2b, or a third redundant light-emitting element ED3b which corresponds to the first light-emitting element ED 1a, the second light-emitting element ED2a, or the third light-emitting element ED3a, respectively.

The light-emitting element according to an embodiment of the present disclosure may be a micro-LED. The micro-LED is an LED made of an inorganic material and may be a light-emitting element of 100 μm or smaller.

When implementing the tiling display apparatus by arranging a plurality of display devices, an upper substrate in which the light-emitting element is disposed and a lower substrate in which a driver is disposed are bonded to each other, and a side wiring to electrically connect the upper substrate and the lower substrate to each other is formed in a separate process. However, each display device obtained by bonding each upper and each lower substrate to each other is heavy. When an impact occurs between adjacent display devices such as at an area S during a process of tiling the display devices with each other, the side wiring may be damaged, leading to product defects. A process defect may occur in forming the side wiring through the separate process. To prevent the damage to the side wiring, a side sealing member is introduced. In this case, a weight of the display device is further increased, and it is difficult to minimize a bezel area.

In order to cope with this situation, according to an embodiment of the present disclosure, when the tiling display apparatus TD is implemented by connecting the plurality of display devices 100a, 100b, 100c, . . . 100m and 100n with each other, a spacing between the pixel PX located at the outermost position of one display device and the pixel PX located at the outermost position of another display device adjacent thereto may be the same as a spacing between adjacent pixels PX located in each display device. Accordingly, the bezel area may be disposed in a minimum space or a zero bezel area in which the bezel area is substantially absent may be implemented. When a space occupied by the bezel area is minimized, a display area increases, such that the user recognizes that images appear continuously without discontinuity, and thus the user's screen immersion may increase.

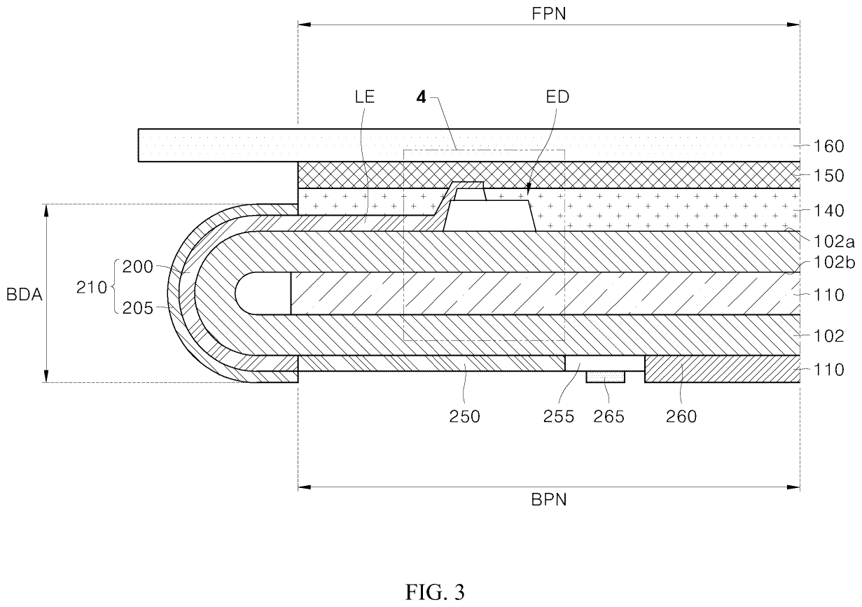

In this case, the quality of the displayed image may be improved by implementing a side structure of the display device so that a seam area as a boundary area between adjacent display devices is not recognized by the user. For example, with reference to FIG. 2 and FIG. 3, each of the plurality of display devices 100a, 100b, . . . 100m, and 100n may be composed of a single substrate 102 as one sheet.

The substrate 102 may include a front panel area FPN, a bendable area BDA, and a back panel area BPN, and may be one sheet. The bendable area BDA is a portion that may be bent so that the back panel area BPN faces the front panel area FPN. The front panel area FPN located on one side of the bendable area BDA may have a first width W1, and the back panel area BPN located on the other side thereof may have a second width W2 equal to the first width W1. The display device may be divided into a display area AA where light is emitted and a non-display area NAA excluding the display area AA. The front panel area FPN may correspond to the display area AA, while the bendable area BDA, and the back panel area BPN may correspond to the non-display area NAA.

In the display area AA, a plurality of pixels PX where light-emitting elements that emit light are disposed, and connection wirings LE that transmit signals to the pixels PX may be disposed on the substrate 102 and in the front panel area FPN. A driver including a circuit film 255 on which an integrated circuit chip 265 to transmit various driving signals to each sub-pixel disposed on the front panel area FPN is mounted, and a printed circuit board 260 connected to the circuit film 255 may be disposed on the substrate 102 and in the back panel area BPN. An output signal wiring 250 for transmitting signals generated from the driver including the integrated circuit chip 265 to the display area corresponding to the front panel area FPN may be disposed on the substrate 102 and in the back panel area BPN. In this regard, the output signal wiring 250 may include, but is not limited to, a high-potential voltage (VDD) line.

On the substrate 102 and in the bendable area BDA disposed between the front panel area FPN and the back panel area BPN, a side wiring portion 210 for transmitting the signal transmitted from the output signal wiring 250 to the light-emitting element ED on the front panel area FPN may be disposed. The side wiring portion 210 may include a conductive connection portion 200 and a protecting portion 205. Adjacent conductive connection portions of the side wiring portion 210 may be arranged to be spaced apart from each other by a predetermined distance.

The protecting portion 205 serves to prevent the conductive connection portion 200 from being damaged during a bending operation in which the bendable area BDA is bent. Description thereof will be provided later.

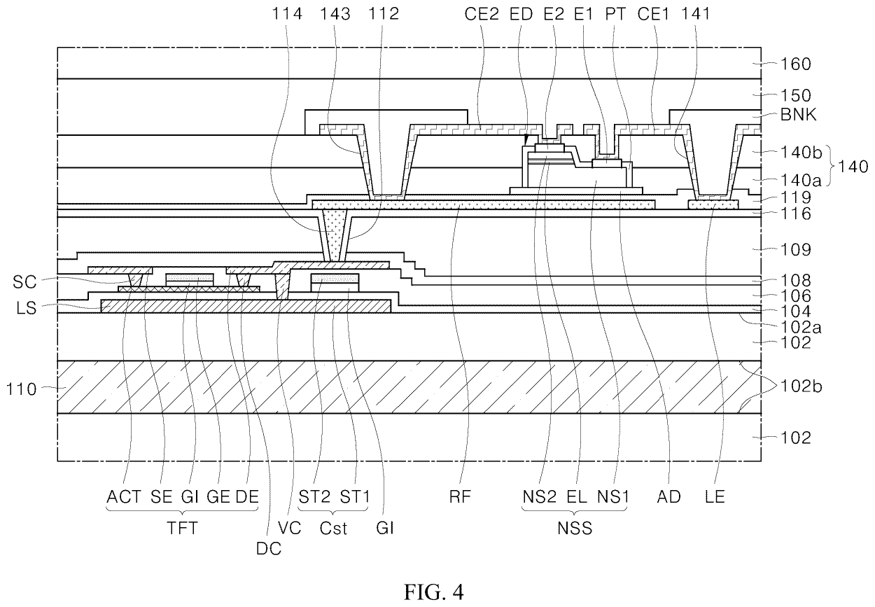

FIG. 3 is a cross-sectional view of a display device according to one embodiment of the present disclosure. FIG. 4 is an enlarged view of an area 4 in FIG. 3. In this regard, in the drawing, only one light-emitting element ED located at the outermost position of the display device is shown for convenience of illustration.

With reference to FIG. 3 and FIG. 4, the display device 100 according to one embodiment of the present disclosure may include a single substrate 102. The substrate 102 includes the front panel area FPN, the back panel area BPN, and the bendable area BDA located between the front panel area FPN and the back panel area BPN. The substrate 102 may have the bendable area BDA bent so that the back panel area BPN faces the front panel area FPN.

The substrate 102 may be made of a flexible, transparent insulating material. For example, the substrate 102 may include polyimide (PI). Introducing the substrate 102 made of a flexible and lightweight material may allow the product to be lighter.

A plurality of circuit elements may be disposed in the front panel area FPN corresponding to the display area AA and on a first surface 102a of the substrate 102. Each of the plurality of circuit elements includes the light-emitting element ED that emits light and a thin-film transistor TFT to drive the light-emitting element ED. The driver including the circuit film 255 on which the integrated circuit chip 265 is mounted and the printed circuit board 260 connected to the circuit film 255 may be disposed on the first surface 102a of the substrate 102 and in the back panel area BPN. The output signal wiring 250 to transmit signals generated from the driver to the light-emitting element ED may be disposed on the first surface 102a of the substrate 102 and in the back panel area BPN. The side wiring portion 210 may be disposed on the first surface 102a of the substrate 102 and in the bendable area BDA.

A support member 110 may be disposed on a second surface 102b opposite the first surface 102a of the substrate 102 and in a space defined by the front panel area FPN and the back panel area BPN facing each other. The support member 110 may supplement the rigidity of the substrate 102 and maintain the bent shape of the bendable area BDA so that the back panel area BPN faces the front panel area FPN. Accordingly, the second surface 102b of the substrate 102 in the back panel area BPN may be fixed to the second surface 102b of the substrate 102 in the front panel area FPN. In this regard, the first surface 102a of the substrate 102 may be referred to as a front surface, and the second surface 102b of the substrate 102 may be referred to as a rear surface.

Due to the configuration in which the bendable area BDA of the substrate 102 is bent, each of both opposing surfaces of the support member 110 may contact an exposed portion of the second surface 102b of the substrate 102.

The connection wiring LE serves to transmit driving signals to the light-emitting element ED and the thin-film transistor TFT. The connection wiring LE may be electrically connected to the output signal wiring 250 on the back panel area BPN via the side wiring portion 210 and may transmit the signal transmitted from the driver to the light-emitting element ED and the thin-film transistor TFT on the front panel area FPN.

Various circuit elements including the light-emitting element ED and the thin-film transistor TFT for driving the light-emitting element ED and various lines connecting the various circuit elements to each other may be disposed on the substrate 102. Hereinafter, an enlarged view of an area 4 where the light-emitting element ED is disposed in FIG. 3 will be described with reference to FIG. 4.

With reference to FIG. 4, the thin-film transistor TFT, a storage capacitor Cst, and a plurality of lines that are used to drive the light-emitting element ED are disposed on the first surface 102a of the substrate 102. The thin-film transistor TFT may drive the light-emitting element ED. The storage capacitor Cst may store therein the voltage set so that the light-emitting element ED is maintained in the same state for one frame. The second surface 102b may be a surface facing the first surface 102a of the substrate 102. The support member 110 may be disposed on the second surface 102b. In this regard, the first surface 102a may be referred to as the front surface. The second surface 102b may be referred to as the rear surface.

The support member 110 is in contact with the second surface 102b of the substrate 102 and strengthens the rigidity of the substrate 102 while bonding the front panel area FPN and the back panel area BPN of the substrate 102 to each other. Furthermore, the support member 110 may maintain the flexibility of the substrate 102 made of a flexible material. The support member 110 may have a single-layer or multi-layer structure. The support member 110 will be described later with reference to FIG. 10 to FIG. 12.

A light-blocking layer LS may be disposed on the first surface 102a of the substrate 102. The light-blocking layer LS may reduce leakage current by preventing light incident from a position under a bottom of the substrate 102 from being incident to an active layer of the plurality of thin-film transistors. For example, the light-blocking layer LS may be disposed under the active layer ACT of the thin-film transistor TFT that functions as a driving transistor to prevent the light from being incident on the active layer ACT.

A buffer layer 104 is disposed on the light-blocking layer LS. The buffer layer 104 may prevent impurities or moisture penetrating through the substrate 102 from invading the thin-film transistor TFT. The buffer layer 104 may include an insulating material such as silicon oxide (SiOx) or silicon nitride (SiNx).

The thin-film transistor TFT is disposed on the buffer layer 104. The thin-film transistor TFT may include a semiconductor layer ACT, a gate electrode GE, a source electrode SE, and a drain electrode DE. A gate insulating layer GI may be disposed between the semiconductor layer ACT and the gate electrode GE.

The semiconductor layer ACT may include an active area that overlaps the gate electrode GE to form a channel, and a source area and a drain area respectively located on both opposing sides of the active area. A first interlayer insulating film 106 is disposed on the gate electrode GE. The first interlayer insulating film 106 may receive therein a source contact SC and a drain contact DC. The source contact SC and drain contact DC may respectively contact portions of surfaces of the source area and the drain area of the semiconductor layer ACT. The source contact SC and the drain contact DC may be respectively electrically connected to the source electrode SE and the drain electrode DE located on a top surface of the first interlayer insulating film 106 and electrically connected to the source and drain areas of the semiconductor layer ACT, respectively.

The storage capacitor Cst may include a first capacitor electrode ST1 and a second capacitor electrode ST2. The first capacitor electrode ST1 may be disposed between the substrate 102 and the buffer layer 104. The first capacitor electrode ST1 may be integrated with the light-blocking layer LS. A combination of the buffer layer 104 and the gate insulating layer GI may act as a dielectric layer of the storage capacitor Cst on the first capacitor electrode ST1. The second capacitor electrode ST2 may be disposed on the gate insulating layer GI. The second capacitor electrode ST2 may be made of the same material as that of the gate electrode GE.

A first passivation layer 108 is disposed on the source electrode SE and the drain electrode DE. The first passivation layer 108 serves to protect the thin-film transistor TFT and may include an insulating material. A first planarization layer 109 is disposed on the first passivation layer 108. The first planarization layer 109 serves to planarize a surface step caused by an underlying element such as the thin-film transistor TFT. The first planarization layer 109 may be configured to include a photoactive compound (PAC). However, the present disclosure is not limited thereto.

The first planarization layer 109 may receive therein a contact hole 112 exposing a portion of a surface of the drain electrode DE. A second interlayer insulating film 116 may be disposed on a side surface of the contact hole 112 and the first planarization layer 109. A via contact 114 fills the contact hole 112. The drain electrode DE connected to one surface of the via contact 114 may be electrically connected to the light-blocking layer LS via a through-electrode VC extending through the first interlayer insulating film 106 and the buffer layer 104.

A reflective electrode RF may be disposed on the via contact 114 and the second interlayer insulating film 116. The reflective electrode RF reflects light emitted from the light-emitting element toward the substrate 102 so as to be directed out of the display area. The reflective electrode RF may include a highly reflective metal material. For example, the metal material with high reflectivity may include aluminum (Al), copper (Cu), silver (Ag), molybdenum (Mo), gold (Au), magnesium (Mg), calcium (Ca), or barium (Ba). The reflective electrode RF may include a single-layer structure or a stack structure made of one selected from aluminum (Al), copper (Cu), silver (Ag), molybdenum (Mo), gold (Au), magnesium (Mg), calcium (Ca), or barium (Ba) or an alloy material of at least two thereof. One surface of the reflective electrode RF may contact the via contact 114 such that the reflective electrode RF may be electrically connected to the drain electrode DE.

The signal line LE may be disposed so as to be coplanar with the reflective electrode RF. The signal line LE may include a plurality of signal lines. The plurality of signal lines may include a high-potential voltage line VDDL, a low-potential voltage line VSSL, a reference voltage line RL, a data line DL, and a scan line SL. A second passivation layer 119 may be disposed so as to cover the reflective electrode RF.

The light-emitting element ED may be disposed on the second passivation layer 119 and may be bonded thereto via an adhesive layer AD. The light-emitting element ED may include a nitride semiconductor structure NSS, a first electrode E1 and a second electrode E2. The nitride semiconductor structure NSS may include a first semiconductor layer NS1, an active layer EL disposed in one side of a top surface of the first semiconductor layer NS1, and the second semiconductor layer NS2 disposed on the active layer EL. The first electrode E1 may be disposed in the other side of the top surface of the first semiconductor layer NS1 where the active layer EL is not located, and the second electrode E2 is disposed on the second semiconductor layer NS2. A protective layer pattern PT such as a passivation pattern may cover an outer surface of the light-emitting element ED. In one embodiment of the present disclosure, an example in which the light-emitting element ED has a lateral type structure is described. However, the present disclosure is not limited thereto. For example, the light-emitting element ED may have a vertical type structure.

The first semiconductor layer NS1 is a layer for supplying electrons to the active layer EL and may include a nitride semiconductor containing first conductivity type impurity. For example, the first conductivity type impurity may include N type impurity. The active layer EL disposed in one side of the top surface of the first semiconductor layer NS1 may include a multi quantum well (MQW) structure. The second semiconductor layer NS2 is a layer for injecting holes into the active layer EL. The second semiconductor layer NS2 may include a nitride semiconductor containing second conductivity type impurity. For example, the second conductivity type impurity may include P type impurity.

The light-emitting element ED may be covered with an upper planarization layer 140 having a first opening hole 141 and a second opening hole 143 defined therein. The upper planarization layer 140 may include a structure in which a second planarization layer 140a and a third planarization layer 140b are stacked.

The first electrode E1 and the second electrode E2 of the light-emitting element ED may be electrically connected to a first line electrode CE1 and a second line electrode CE2, respectively. The first line electrode CE1 may be electrically connected to the connection wiring LE. The second line electrode CE2 may be electrically connected to the drain electrode DE via the reflective electrode RF.

The first opening hole 141 and the second opening hole 143 may be filled with a material constituting a bank BNK. A sealing protection layer 150 may be disposed on the upper planarization layer 140 and the bank BNK. A cover member 160 is disposed on the sealing protection layer 150. The cover member 160 may be disposed on a portion of the sealing protection layer 150 on at least the front panel area FPN. The cover member 160 may further include a functional optical film such as an anti-shatter film.

In order to stably supply the driving signals supplied from the driver on the back panel area BPN to circuit elements such as the light-emitting element ED or the thin-film transistor TFT on the front panel area FPN, resistance stability of the side wiring portion 210 disposed on the bendable area BDA must be maintained. For example, as the change in the resistance thereof decreases, stability in the electrical conductivity of the side wiring portion 210 may be maintained. As the change in the resistance thereof increases, stability in the electrical conductivity decreases and thus, the reliability of the display device may decrease.

Accordingly, in an embodiment of the present disclosure, the side wiring portion 210 is composed of the conductive connection portion 200 and the protecting portion 205 integrated with each other to prevent cracks occurring in the conductive connection portion 200 or change in the resistance thereof. Furthermore, forming the conductive connection portion 200 and the protecting portion 205 in the integrated manner into one body may allow the conductive connection portion 200 to be prevented from being damaged by external impact. Thus, a side sealing member may be omitted.

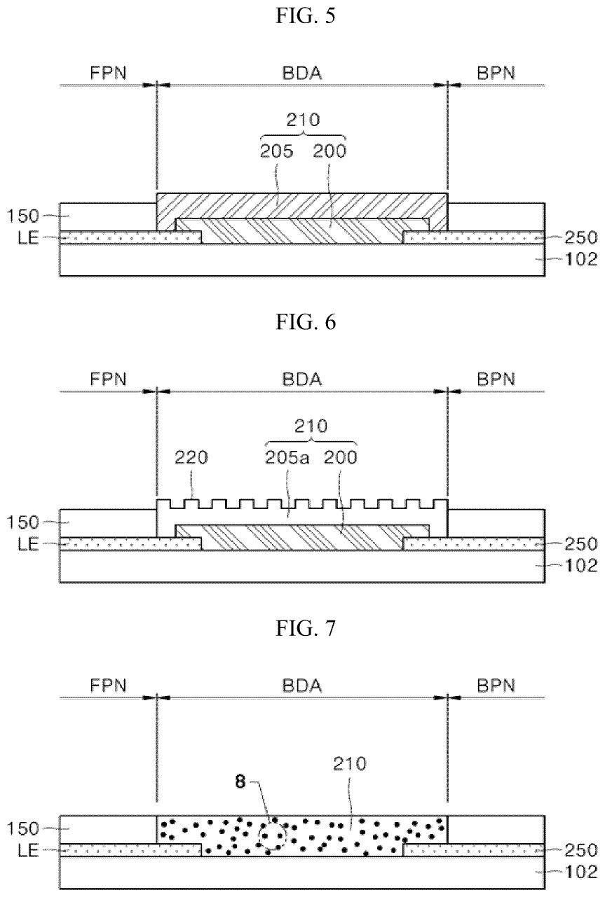

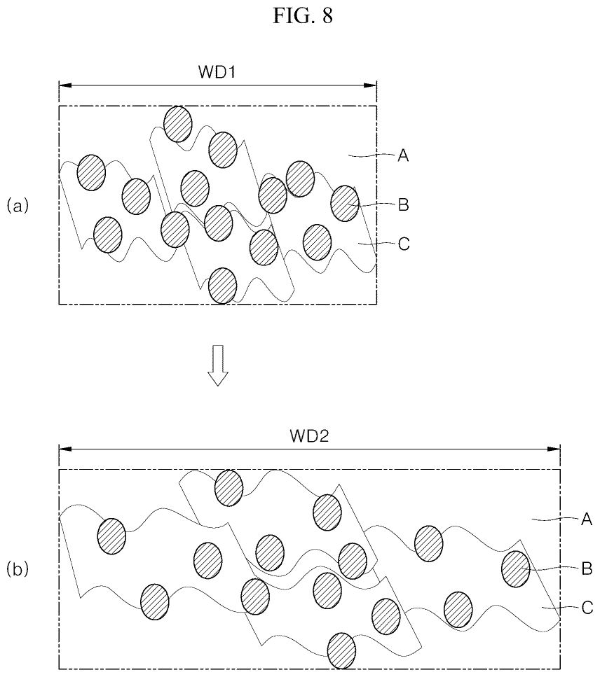

The side wiring portion will be described below with reference to FIG. 5 to FIG. 8. FIG. 5 to FIG. 8 are drawings shown to illustrate the side wiring portion. In this regard, FIG. 5 shows a side wiring portion according to one embodiment of the present disclosure. Furthermore, FIG. 6 shows a side wiring portion according to another embodiment. FIG. 7 and FIG. 8 show a side wiring portion according to still another embodiment.

With reference to FIG. 5, the side wiring portion 210 may include the conductive connection portion 200 and a first protecting portion 205. The side wiring portion 210 is located on the bendable area BDA and electrically connects the connection wiring LE disposed on the front panel area FPN and the output signal wiring 250 disposed on the back panel area BPN to each other.

The conductive connection portion 200 may be located on the bendable area BDA and may be electrically connected to each of the connection wiring LE and the output signal wiring 250, respectively. In this regard, one side end of the conductive connection portion 200 may overlap a portion of the connection wiring LE. The other side end of the conductive connection portion 200 may overlap a portion of the output signal wiring 250. The conductive connection portion 200 may include a metal material in a form of particles or flakes. Alternatively, the conductive connection portion 200 may include a nanowire-shaped metal electrode material that may be implemented into a mesh shape. The conductive connection portion 200 may be configured to further include an acryl or epoxy-based binder along with the metal material.

The first protecting portion 205 may include a material with low modulus to prevent cracks from occurring in the conductive connection portion 200 even when bending deformation at a radius of 1 mm or smaller occurs. For example, the material with low elasticity may include an opaque urethane-based material. The side wiring portion 210 including the conductive connection portion 200 and the first protecting portion 205 may have the resistance change of 10% or smaller even when bending deformation of the bendable area BDA at a radius of 1 mm or smaller occurs.

After a process of forming the light-emitting element ED and the output signal wiring 250 on the front panel area FPN and the back panel area BPN, respectively has been completed, the conductive connection portion 200 of the side wiring portion 210 may be formed by printing an electrode material on the bendable area BDA. The first protecting portion 205 may be formed by coating the material constituting the first protecting portion 205 on the conductive connection portions 200.

Furthermore, due to a shape of the protecting portion, the cracks may be prevented from occurring in the conductive connection portion 200 even when the bending deformation of the bendable area BDA occurs. This will be described with reference to FIG. 6 below.

With reference to FIG. 6, the side wiring portion 210 may be configured to include the conductive connection portion 200 and a second protecting portion 205a that covers the conductive connection portion 200. The second protecting portion 205a may include a wrinkle pattern 220 in which an upper surface of the second protecting portion 205a has a concavo-convex shape. When the bendable area BDA is deformed to be bent, the wrinkle pattern 220 of the second protecting portion 205a is stretched so as be flat such that the conductive connection portion 200 located under the wrinkle pattern 220 may be prevented from being damaged by the crack.

Furthermore, the side wiring portion 210 may be made of a composite of a wiring material and a material of a wiring protection layer so that the side wiring portion may be stretched and maintain electrical conductivity even under bending deformation thereof. With reference to FIG. 7 and FIG. 8, the side wiring portion 210 made of the composite is located on the bendable area BDA and may be electrically connected to the connection wiring LE on the front panel area FPN and to the output signal wiring on the back panel area BPN. One side end of the side wiring portion 210 may overlap a portion of the connection wiring LE on the front panel area FPN, while the other side end thereof may overlap a portion of the output signal wiring on the back panel area BPN.

The side wiring portion 210 may include an electrically conductive and stretchable composite layer. For example, the side wiring portion 210 may be configured to include metal nanoparticles B and nanofibers C in an elastomer A. Nanofibers C may include graphene oxide or cellulose composite. Thus, a configuration in which the conductive connection portion and the protecting portion are integrated with each other into one body may be implemented.

The side wiring portion 210 having this configuration may have a first length WD1, as shown in (a) of FIG. 8, before the bending deformation occurs. Then, when the bending deformation occurs, the side wiring portion 210 may be stretched to a second length WD2 which is larger than the first length WD1, due to the stretchable elastomer A and the nanofiber C, as shown in (b) in FIG. 8. Accordingly, the cracks may be prevented from occurring due to the stretchable composite layer while the electrical conductivity may be maintained using the metal nanoparticles B.

In accordance with the present disclosure, the side wiring portion 210 may be composed of the conductive connection portion 200 and the protecting portion 205 which are integrated with each other into one body. Alternatively, the side wiring portion 210 may be embodied as an electrically conductive and stretchable composite layer. This may prevent the cracks from occurring or the resistance change in the conductive connection portion 200.

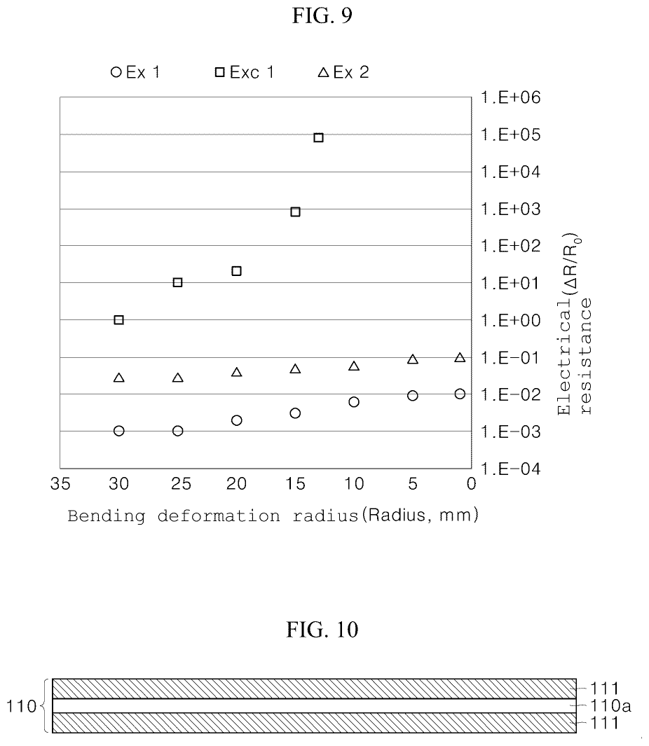

FIG. 9 is a graph showing the change in the resistance during the bending deformation.

With reference to FIG. 9, it may be identified that in Comparative Example Exc 1 in which the side wiring portion is formed using a deposition scheme, a resistance change value increases as a bending deformation radius decreases. To the contrary, according to an embodiment of the present disclosure, it may be identified that in Present Example 1 Ex1 in which the conductive connection portion 200 of the side wiring portion 210 is formed in a printing scheme, or in Present Example 2 Ex2 in which the side wiring portion 210 is made of the composite layer that may be stretched and may be electrically conductive, as shown in FIG. 7, the resistance change value is within 10% even at the bending deformation at a radius of 1 mm or smaller.

As a result, the side wiring portion 210 according to an embodiment of the present disclosure may have the low change in the resistance and thus may maintain the resistance stability. Thus, the reliability of the display device may be secured.

In one example, the support member 110 in contact with the second surface 102b of the substrate 102 may bond the front panel area FPN and the back panel area BPN of the substrate 102 to each other. Furthermore, the flexibility of the substrate 102 may be maintained while the rigidity thereof may be supplemented due to the material and the shape of the support member 110, thereby preventing damage to circuit elements such as the light-emitting element ED due to external impact.

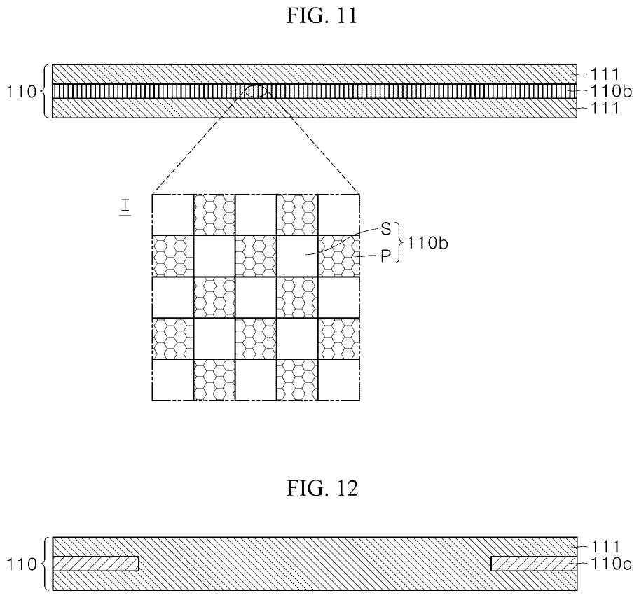

The shape of the support member 110 will be described below with reference to FIG. 10 to FIG. 12. FIG. 10 to FIG. 12 are cross-sectional views showing the shape of the support member. In this regard, FIG. 10 shows a support member according to one embodiment of the present disclosure. Furthermore, FIG. 11 shows support members according to another embodiment. FIG. 12 shows a support member according to still another embodiment.

With reference to FIG. 10, the support member 110 may include a first core layer 110a and upper and lower adhesive members 111 respectively disposed on both opposing surfaces of the first core layer 110a while the first core layer 110a is disposed therebetween. The first core layer 110a and each of the adhesive members 111 may have a rectangular plate shape. The first core layer 110a complements the rigidity of the substrate 102 and may include a hard and rigid material such as polyethylene terephthalate (PET), polycarbonate (PC), or polymethylmethacrylate (PMMA).

The upper and lower adhesive members 111 respectively in contact with both opposing surfaces of the first core layer 110a may contact the second surface 102b of the substrate 102 in the front panel area FPN and the second surface 102b of the substrate 102 in the back panel area BPN, respectively, and may bond the front panel area FPN and the back panel area BPN to each other to maintain the bent shape of the substrate 102. To this end, each of the adhesive members 111 may include a material that is more flexible and adhesive than the material of the first core layer 110a is. For example, each of the adhesive members 111 may include an acryl, urethane, or silicone-based adhesive resin.

With reference to FIG. 11, the support member 110 according to another embodiment may include a second core layer 110b having a pattern shape and the upper and lower adhesive members 111 respectively disposed on both opposing surfaces of the second core layer 110b to maintain the flexibility of the substrate 102. In a top view (a lower diagram) of a partial area I of the second core layer 110b of a cross-sectional view (an upper diagram) of FIG. 11, a plurality of partial patterns P may be arranged in a checkerboard manner in which a space S may be disposed between adjacent partial patterns P. The flexible adhesive member 111 may be disposed in the space S disposed between adjacent ones of the plurality of partial patterns P. As a result, an area size of the flexible adhesive member 111 may increase, such that the flexibility of the substrate 102 may be further improved.

Furthermore, with reference to FIG. 12, the support member 110 according to another embodiment may include an adhesive member 111 and a third core layer 110c received in the adhesive member 111. The adhesive member 111 may have a rectangular plate shape corresponding to that of the substrate 102. The third core layer 110c may be located in an edge area of the adhesive member 111 and may have a rectangular ring frame shape extending along four edges of the adhesive member 111 which has a rectangular plate shape. As the third core layer 110c has the rectangular ring frame shape having an empty inner area defined therein, the empty inner area may be filled with the adhesive member. As a result, the rigidity of the substrate 102 may be supplemented with the third core layer 110c to prevent damage thereto from external impact, and, at the same time, the flexibility of the substrate 102 may be maintained due to the adhesive member 111 including the flexible material.

According to an embodiment of the present disclosure, the display device may be manufactured using one substrate. Thus, the process of separately manufacturing and bonding the upper substrate and the lower substrate to each other may be omitted, thereby optimizing the process and reducing production energy consumption.

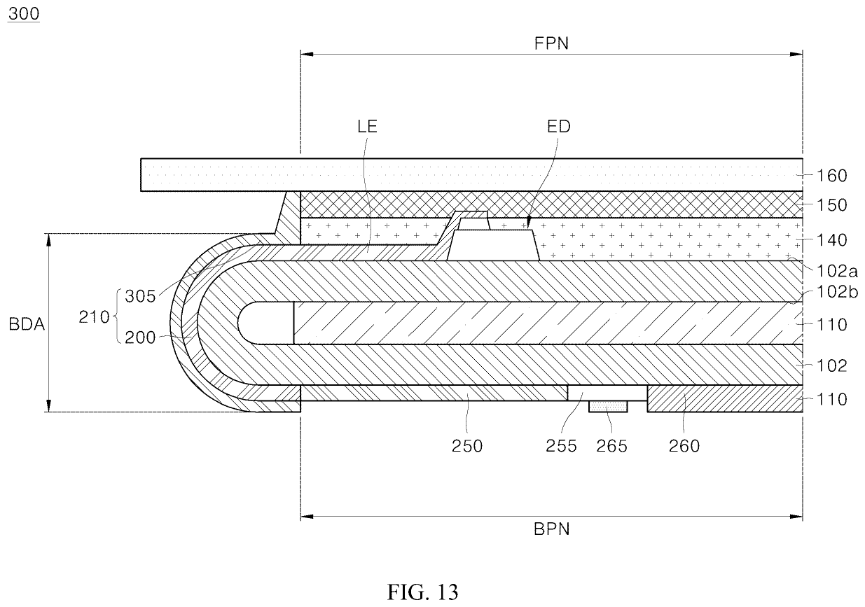

FIG. 13 is a cross-sectional view of a display device according to another embodiment of the present disclosure. A display device 300 according to another embodiment of the present disclosure is the same as the display device 100 of the embodiment in FIG. 3 except for a shape of the protecting portion 305 of the side wiring portion 210. Thus, duplicate descriptions will be omitted.

With reference to FIG. 13, the side wiring portion 210 of the display device 300 according to another embodiment of the present disclosure may include the conductive connection portion 200 and a protecting portion 305 that covers the conductive connection portion 200, wherein the protecting portion 305 covers a side end surface of each of the upper planarization layer 140 and the sealing protection layer 150. The protecting portion 305 may be formed by coating a black bank onto the conductive connection portion 200.

The protecting portion 305 of the side wiring portion 210 covers the side end surface of each of the upper planarization layer 140 and the sealing protection layer 150 to prevent moisture or foreign materials from penetrating into the upper planarization layer 140 and the sealing protection layer 150. Accordingly, the stability of the display device 300 may be further improved.

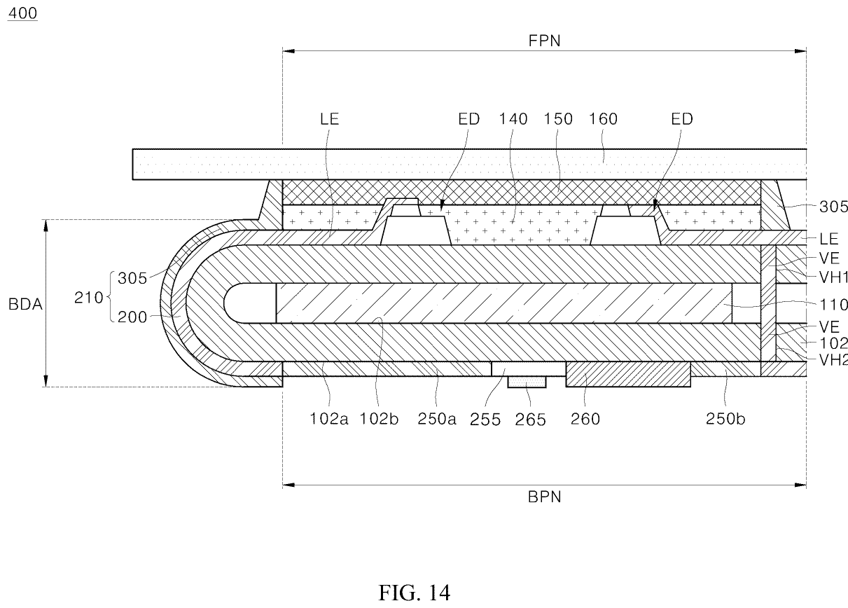

FIG. 14 is a cross-sectional view of a display device according to still another embodiment of the present disclosure. Since a display device 400 according to still another embodiment of the present disclosure is the same as the display device 300 of the embodiment of FIG. 13 except for, for example, a through-electrode VE. Thus, duplicate descriptions will be omitted below. In this regard, in the drawing, only the light-emitting elements ED respectively located at both opposing outermost sides of the display device are shown for convenience of illustration.

With reference to FIG. 14, the side wiring portion 210 is disposed on the bendable area BDA at one side of the display device 400 according to still another embodiment of the present disclosure. Further, at the other side opposite to the one side of the display device 400 according to still another embodiment of the present disclosure, a first through-hole VH1 extends through the front panel area FPN of the substrate 102, a second through-hole VH2 extends through the back panel area BPN of the substrate 102, and the through-electrode VE fills the first through-hole VH1 and the second through-hole VH2.

On the back panel area BPN, the driver including the circuit film 255 on which the integrated circuit chip 265 to transmit various driving signals to each sub-pixel disposed on the front panel area FPN is mounted, and the printed circuit board 260 connected to the circuit film 255 may be disposed. On the back panel area BPN, a first output signal wiring 250a extending toward the bendable area BDA and a second output signal wiring 250b extending toward the through-electrode VE may be disposed. In this regard, the first output signal wiring 250a and the second output signal wiring 250b may transmit different output signals. For example, the first output signal wiring 250a may transfer high-potential voltage VDD, and the second output signal wiring 250b may transfer low-potential voltage VSS. However, the present disclosure is not limited thereto.

In the display device 400 according to still another embodiment of the present disclosure, different output signals may be respectively output toward both opposing sides of one substrate 102. Thus, the display device may operate at low power, thereby reducing power consumption.

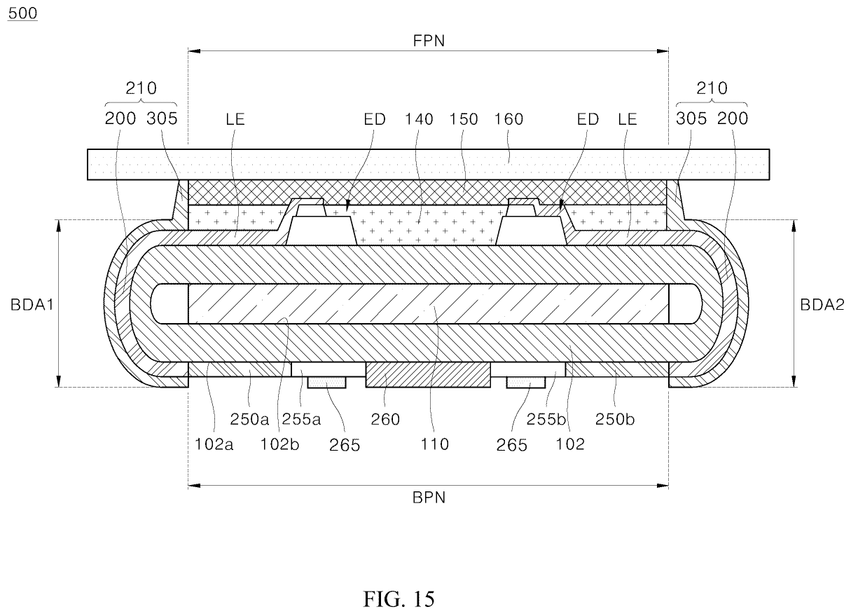

FIG. 15 is a cross-sectional view of a display device according to still yet another embodiment of the present disclosure. A display device 500 according to still yet another embodiment of the present disclosure is the same as the display device 400 of the embodiment of FIG. 13 except for, for example, a configuration that the display device further includes a second bendable area BDA2. Thus, duplicate descriptions are omitted below. In this regard, in the drawing, only the light-emitting elements ED respectively located at the outermost both opposing sides of the display device are shown for convenience of illustration.

With reference to FIG. 15, the display device 500 according to still yet another embodiment of the present disclosure may include a plurality of bendable areas BDA1 and BDA2 disposed between the front panel area FPN and the back panel area BPN. The plurality of bendable areas BDA1 and BDA2 include the first bendable area BDA1 at one side of the display device 500 that is bent so that the back panel area BPN faces the front panel area FPN, and the second bendable area BDA2 at the other side of the display device 500 which is bent so that the back panel area BPN faces the front panel area FPN. The side wiring portion 210 may be disposed on each of the first bendable area BDA1 and the second bendable area BDA2. Each of the side wiring portion 210 may include the conductive connection portion 200 and the protecting portion 305 which covers the conductive connection portion 200 and extends so as to cover the side end surface of each of the upper planarization layer 140 and the sealing protection layer 150. The protecting portion 305 may be formed by coating the black bank onto the conductive connection portions 200.

On the back panel area BPN, the driver including the circuit film 255 on which the integrated circuit chip 265 to transmit various driving signals to each sub-pixel disposed on the front panel area FPN is mounted, and the printed circuit board 260 connected to the circuit film 255 may be disposed.

On the back panel area BPN, the first output signal wiring 250a extending toward the first bendable area BDA1 and the second output signal wiring 250b extending toward the second bendable area BDA2 may be disposed. In this regard, the first output signal wiring 250a and the second output signal wiring 250b may transmit different output signals. For example, the first output signal wiring 250a may transfer high-potential voltage VDD, and the second output signal wiring 250b may transfer low-potential voltage VSS. However, the present disclosure is not limited thereto.

According to an embodiment of the present disclosure, one substrate includes the front panel area, the back panel area, and the bendable area. The side wiring portion that electrically connects the light-emitting element on the front panel area and the driver on the back panel area to each other is formed on the bendable area so as to have the integrated structure. Thus, the stability and reliability of the side wiring portion may be improved. Furthermore, forming the side wiring portion into the integrated structure on the bendable area may allow the damage caused by impact between adjacent tiling display devices to be reduced when arranging a plurality of tiling display devices with each other. Thus, the side sealing member may be omitted, thereby minimizing the bezel area or implementing a zero bezel.

Furthermore, the side wiring portion may be formed on the bendable area so as to have the integrated structure, such that the side sealing member may be omitted, thereby reducing a weight of the display device through a uni-material.

Further aspect of the present disclosure provides a method for manufacturing a display device comprising: enabling a substrate including a front panel area, a back panel area, and a bendable area between the front panel area and the back panel area; disposing a plurality of light-emitting elements in a display area located on the front panel area of the substrate; disposing an integrated circuit chip in the back panel area of the substrate; and disposing a side wiring portion in the bendable area of the substrate so as to electrically connect the light-emitting elements and the integrated circuit chip to each other, wherein the side wiring portion includes a conductive connection portion, and a protecting portion covering the conductive connection portion.

Furthermore, the display device includes a single substrate including the front panel area, the back panel area, and the bendable area disposed between the front panel area and the back panel area.

Although the embodiments of the present disclosure have been described in more detail with reference to the accompanying drawings, the present disclosure is not necessarily limited to these embodiments and may be modified in a various manner in the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device, comprising:
a substrate including a front panel area, a back panel area, and a bendable area disposed between the front panel area and the back panel area;
a display area located on the substrate and in the front panel area and having a plurality of light-emitting elements;
an integrated circuit chip located on the substrate and in the back panel area; and
a side wiring portion located on the substrate and in the bendable area so as to electrically connect the light-emitting elements and the integrated circuit chip to each other,
wherein the side wiring portion includes a conductive connection portion and a protecting portion covering the conductive connection portion.

2. The display device of claim 1, further comprising:
a connection wiring located in the front panel area and configured to transmit a signal from the integrated circuit chip to each of the plurality of light-emitting elements; and
an output signal wiring located in the back panel area so as to receive the signal from the integrated circuit chip and transmit the signal to the front panel area,
wherein the side wiring portion electrically connects the connection wiring and the output signal wiring to each other.

3. The display device of claim 1, wherein one side end of the conductive connection portion of the side wiring portion overlaps a portion of the connection wiring, and the other side end of the conductive connection portion of the side wiring portion overlaps a portion of the output signal wiring.

4. The display device of claim 1, wherein:
the conductive connection portion includes a metal material in a form of particles or flakes or a metal electrode material in a form of a nanowire able to be implemented in a mesh shape, and
the protecting portion includes a material with low elasticity.

5. The display device of claim 1, wherein an upper surface of the protecting portion has a wrinkle pattern having a convex-concave shape.

6. The display device of claim 1, wherein:
the side wiring portion includes a composite including an elastomer, and metal nanoparticles, and/or nanofibers dispersed in the elastomer, and
the nanofiber includes graphene oxide or cellulose composite.

7. The display device of claim 1, wherein the display device further comprises a support member for fixing a rear surface of the back panel area of the substrate to a rear surface of the front panel area of the substrate facing the back panel area.

8. The display device of claim 7, wherein the support member includes:
a core layer in a shape of a rectangular plate; and
upper and lower adhesive members respectively disposed on both opposing surfaces of the core layer, and
wherein each of the upper and lower adhesive members has flexibility greater than flexibility of the core layer.

9. The display device of claim 7, wherein the support member includes:
a core layer includes a plurality of partial patterns arranged in a checkerboard manner in a plan view of the display device, wherein a space is disposed between adjacent ones of the partial patterns; and
adhesive members respectively disposed on both opposing surfaces of the core layer, adhesive members including an upper adhesive member and a lower adhesive member.

10. The display device of claim 7, wherein the support member includes:
an adhesive member in a shape of a rectangular plate; and
a core layer received in the adhesive member and having a rectangular ring frame shape extending along four edge sides of the adhesive member.

11. The display device of claim 1, wherein:
the front panel area of the substrate further comprises an upper planarization layer covering the plurality of light-emitting elements, and a sealing protective layer disposed on the upper planarization layer, and
the protecting portion covers the conductive connection portion and extends so as to cover a side end surface of each of the upper planarization layer and the sealing protection layer.

12. The display device of claim 1, further comprising:
a first through hole disposed at the other side of the display device opposite to one side of the display device at which the bendable area is disposed, wherein the first through hole extends through the front panel area of the substrate;
a second through hole disposed at the other side of the display device, wherein the second through-hole extends through the back panel area of the substrate; and
a through-electrode filling the first through hole and the second through hole.

13. The display device of claim 1, wherein the bendable area includes:
a first bendable area disposed between the front panel area and the back panel area and at one side of the display device; and
a second bendable area disposed between the front panel area and the back panel area and at the other side opposite to the one side of the display device.

14. The display device of claim 1, wherein the light-emitting element is embodied as a micro-LED including:
a nitride semiconductor structure including a first semiconductor layer, an active layer disposed on the first semiconductor layer, and a second semiconductor layer disposed on the active layer;
a passivation pattern disposed on an outer surface of the nitride semiconductor structure;
a first electrode in contact with the first semiconductor layer; and
a second electrode in contact with the second semiconductor layer.

15. A tiling display apparatus in which a plurality of display devices are arranged such that bendable areas of substrates of the plurality of display devices are adjacent to each other,
wherein each of the plurality of display devices includes the display device of claim 1.

16. The tiling display apparatus of claim 15, wherein each of the plurality of display devices includes a single substrate including the front panel area, the back panel area, and the bendable area disposed between the front panel area and the back panel area.
